(19) United States
(12) Patent Application Publication
(10) Pub. No.: US 2009/0243721 A1
(43) Pub. Date: Oct. 1, 2009

(54) FEEDFORWARD AMPLIFIER CIRCUIT AND METHOD FOR CONTROLLING A FEEDFORWARD AMPLIFIER CIRCUIT

(75) Inventors: Wei Jiang, Shanghai (CN); Dai Yong Wang, Shanghai (CN); Wentian Zhang, Keller, TX (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 12/057,399

(22) Filed: Mar. 28, 2008

(51) Int. Cl. H03F 1/32

(52) U.S. Cl. 330/151

(57) ABSTRACT

A feedforward amplifier circuit includes a controllable error signal subtraction module (CESSM). The CESSM has a module signal input, an error cancellation input, a module control input and a circuit output. The module signal input of the CESSM is coupled to a power amplifier via a coupler and delay circuit. The error cancellation input is coupled to a feedforward subtraction module via an error signal amplifier. The module control input is coupled to the output of a controller. In operation, the CESSM subtracts an error cancellation signal from the module signal input. Upon determining a malfunction of the power amplifier, the controller sends a signal to the module control input resulting in the CESSM isolating the module signal input from the circuit output and directly coupling the error cancellation to the circuit output.

### FIELD OF THE INVENTION

The present invention relates generally to feedforward amplifier circuits and a controlling a feedforward amplifier circuits when a malfunction occurs in the power amplifier thereof. The invention is particularly useful for, but not necessarily limited to, mission critical radio communications devices.

### BACKGROUND OF THE INVENTION

Radio Frequency Power Amplifiers are an integral part of radio communications devices that receive an input signal and provide at their output an amplified signal. These Radio Frequency Power Amplifiers have intrinsic non-linear characteristics that, if not corrected a compensation circuit, typically results in the amplified signal being amplitude and phase distorted version of the input signal. One common compensation circuit, used to reduce Radio Frequency Power Amplifier amplitude and phase distortion, is a feedforward compensation circuit that is incorporated into the Radio Frequency Power Amplifier. The combined Radio Frequency Power Amplifier and feedforward compensation circuit is known as a feedforward amplifier in which a feedforward loop provides an error cancellation signal that is subtracted from an amplified signal provided from the Radio Frequency Power Amplifier thereby resulting in a corrected amplified signal provided at the output of the feedforward amplifier.

In mission critical communication systems, the reliability of Radio Frequency Power Amplifiers must be extremely high and therefore fault tolerance, base on hardware redundancy, is often used. Hence, if a Radio Frequency Power Amplifier fails then a backup redundant Amplifier is automatically switched into operation. This form of fault tolerance exploits redundant hardware so that if there are N Power Amplifiers in a communications device then there and an extra M redundant Power Amplifiers that can be switched into operation to replace any faulty ones of the N power amplifiers. Using redundancy, to provide fault tolerance, increases the cost and weight of communications devices and it would therefore be advantageous if feedforward power amplifiers could be configured to provide an alternative to the commonly known redundancy fault tolerant approaches to reliability.

### BRIEF DESCRIPTION OF THE DRAWINGS

In order that the invention may be readily understood and put into practical effect, reference now will be made to exemplary embodiments as illustrated with reference to the accompanying figures, wherein like reference numbers refer to identical or functionally similar elements throughout the separate views. The figures together with a detailed description below, are incorporated in and form part of the specification, and serve to further illustrate the embodiments and explain various principles and advantages, in accordance with the present invention, where:

FIG. 1 is a schematic diagram illustrating a feedforward amplifier circuit in accordance with some embodiments of the disclosure;

FIG. 2 is a schematic diagram illustrating a controllable error signal subtraction module of FIG. 1 in accordance with an embodiment of the disclosure;

FIG. 3 is a schematic diagram illustrating a controllable error signal subtraction module of FIG. 1 in accordance with another embodiment of the disclosure; and

FIG. 4 is a flow diagram illustrating a method for controlling the feedforward amplifier circuit of FIG. 1 in accordance with an embodiment of the disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in a feedforward amplifier circuit and methods for controlling a feedforward amplifier circuit. Accordingly, the feedforward amplifier circuit and methods for controlling a feedforward amplifier circuit have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that device components that comprises a list of elements does not include only those elements but may include other elements not expressly listed or inherent to such feedforward amplifier circuits and methods for controlling a feedforward amplifier circuit. An element proceeded by “comprises . . . a” does not, without more constraints, preclude the existence of additional identical elements in the circuit or methods that comprises the element.

According to one aspect of the present invention there is provided a feedforward amplifier circuit comprising a first coupler with a signal input, a first coupler signal output and a first coupler tertiary output. There is a power amplifier with a power amplifier output and a power amplifier input, the power amplifier input being coupled to the first coupler signal output. A second coupler is provide with ha second coupler input coupled to the power amplifier output, a second coupler signal output and a second coupler tertiary output. The feedforward amplifier circuit has a first delay circuit and a controllable error signal subtraction module with a module signal input coupled through the first delay circuit to the second coupler signal output, the controllable error signal subtraction coupling module having a circuit output, an error cancellation input and a module control input. There is also a second delay circuit and a feedforward subtraction module with a feedforward subtraction module output, a subtraction input coupled through the second delay circuit to the first coupler tertiary output, and an addition input coupled to the second coupler tertiary output. An error signal amplifier couples the feedforward subtraction module output to the error cancellation input and there is a controller with a control output coupled to the module control input. In operation, the controllable error signal subtraction module performs subtraction of an error cancellation signal at the error cancellation input from the module signal input. Upon the controller determining a malfunction of the power amplifier, the controller sends a signal to the module control input resulting in the controllable error signal subtraction module isolating the module signal input from the circuit output and directly coupling the error cancellation input to the circuit output.

According to another aspect of the present invention there is provided a method for controlling a feedforward amplifier circuit by providing, from a power amplifier, an amplified signal of an input signal. Next the method performs creating an error cancellation signal indicative of distortions in the amplified signal. The error cancellation signal is derived from subtracting a reduced amplitude version of the input signal from a reduced amplitude version of the amplified signal to provide an error signal that is amplified by an error signal amplifier thereby creating the error cancellation signal. Then, the method performs subtracting the error cancellation signal from the amplified signal to provide a corrected amplified signal at a circuit output of the feedforward amplifier circuit. A test is performed for determining malfunction of the power amplifier, the determining provides for generating a malfunction signal indicative of the malfunction. The method then performs amplifying the reduced amplitude version of the input signal to provide an amplified version of the input signal; this amplifying is performed by the error signal amplifier in response to the malfunction of the power amplifier. The method also performs isolating the corrected amplified signal from the circuit output, the isolating is in response to the malfunction signal, and then supplying to the circuit output, the amplified version of the input signal, the supplying is in response to the malfunction signal

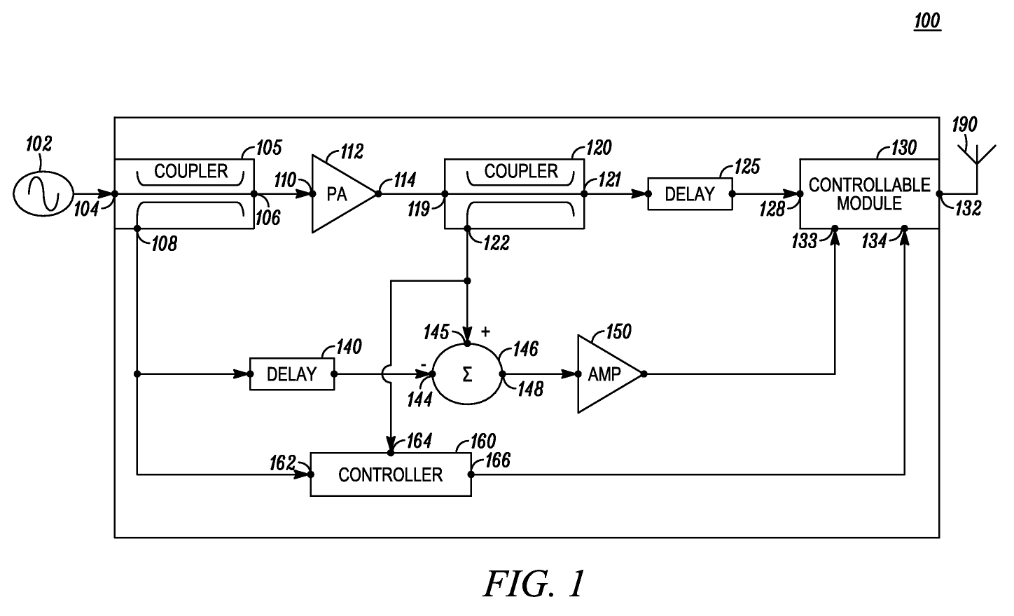

Referring to FIG. 1, there is illustrated a schematic diagram of a feedforward amplifier circuit 100, typically used in a communications devices. The feedforward amplifier circuit 100 includes a first coupler 105 with a first coupler signal input 104 (circuit input) that is coupled to a signal source 102, a first coupler signal output 106 and a first coupler tertiary output 108. There is a power amplifier 112 with a power amplifier output 114 and a power amplifier input 110, the power amplifier input 110 being coupled to the first coupler signal output 106.

The feedforward amplifier circuit 100 also includes a first delay circuit 125 and a second coupler 120 having a second coupler input 119 that is coupled to the power amplifier output 114, a second coupler signal output 121 and a second coupler tertiary output 122. There is a controllable error signal subtraction module 130 with a module signal input 128 coupled through the first delay circuit 125 to the second coupler signal output 121. The controllable error signal subtraction module 130 has a circuit output 132, an error cancellation input 133 and a module control input 134.

The feedforward amplifier circuit 100 has a second delay circuit 140 is coupled to the first coupler tertiary output 108. There is also a feedforward subtraction module 146 with a subtraction input 144 that is coupled, through the second delay circuit 140, to the first coupler tertiary output 108. The feedforward subtraction module 146 also has a feedforward subtraction module output 148 and an addition input 145 that is coupled to the second coupler tertiary output 122.

An error signal amplifier 150 provides a coupling of the feedforward subtraction module output 148 to the error cancellation input 133 of the controllable error signal subtraction module 130. The feedforward amplifier circuit 100 also includes a controller 160 that can be a microprocessor or any other form of control module, with a control output 166, coupled to the module control input 134, and two feedforward amplifier circuit status sensor inputs 162, 164. One of the feedforward amplifier circuit status sensor inputs 162 is coupled to the first coupler tertiary output 108 and the other one of the feedforward amplifier circuit status sensor inputs 164 is coupled to the second coupler tertiary output 122.

The first delay circuit 125 provides a time delay to compensate for propagation delays in the error signal amplifier 150 and feedforward subtraction module 145 and the second delay circuit 140 provides a time delay to compensate for propagation delays in the power amplifier 112. In operation, the controllable error signal subtraction module 130 performs subtraction of an error cancellation signal at the error cancellation input 133 from the module signal input 128. Upon the controller 160 determining a malfunction of the power amplifier 112, the controller 160 sends a signal to the module control input 134 resulting in the controllable error signal subtraction module 130 isolating the module signal input 128 from the circuit output 132 and directly coupling the error cancellation input 133 to the circuit output 132. Typically, in one embodiment, the controller 160 determines malfunction of the power amplifier 112 by monitoring signals at the first coupler tertiary output 108 and the second coupler tertiary output 122. Hence, if an Amplification Ratio (AR) of Pref2/Pref1 provided by the power amplifier 112 falls below an Amplification Reference Threshold Value (ARTV), then the controller 160 determines that there is a malfunction of the power amplifier 112. The ARTV is typically set to a threshold value below the gain of the power amplifier 112 where Pref2 is the signal power at the second coupler tertiary output 122 and Pref1 is the signal power at the first coupler tertiary output 108. It will therefore be apparent to a person skilled in the art that the malfunction of the power amplifier 112 is determined by detecting if the gain of the power amplifier 112 falls below the ARTV.

The circuit output 132 as shown is connected to an antenna 190 and thus the feedforward amplifier circuit 100 is for transmitting radio signals. However, the feedforward amplifier circuit 100 may be part of a radio receiver and may therefore have an antenna as the signal source 102 and the circuit output 132 connected to demodulation circuitry instead of the antenna 190.

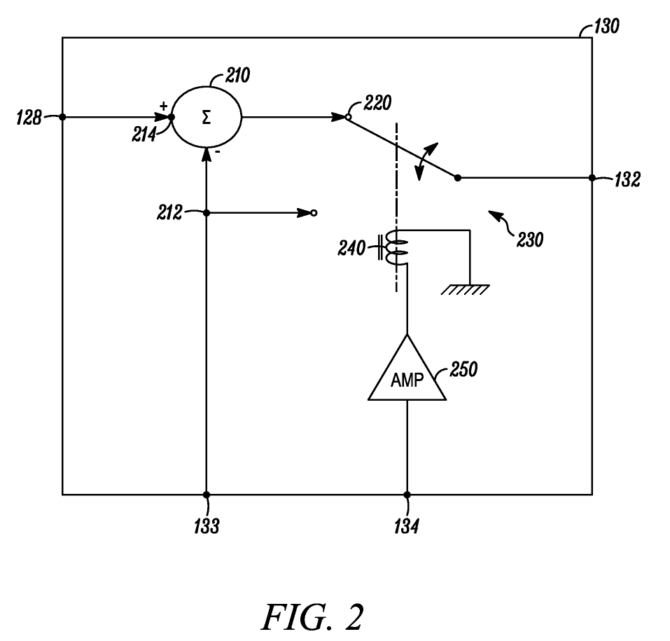

Referring to FIG. 2 there is illustrated an embodiment of the controllable error signal subtraction module 130 that comprises a selectable subtraction module 210 with an isolatable output 220 coupled through a switch 230 to the circuit output 132. The selectable subtraction module 210 has a module subtraction input 212 coupled to the error cancellation input 133 and a module addition input 214 coupled to the module signal input 128. The switch 230 is a reed relay with a relay coil 240 that is energizable by an amplifier 250 having an input coupled to the module control input 134 and therefore the switch 230 (reed relay) is controllable by the module control input 134. The switch 230 either directly couples the isolatable output 220 to the circuit output 132 or alternatively isolates the isolatable output 220 from the circuit output 132 and directly couples the error cancellation input 133 to the circuit output 132. It will therefore be apparent to a person skilled in that art that, in operation, the error signal subtraction module 210 performs subtraction of an error cancellation signal at the error cancellation input 133 from the module signal input 128. Also, upon the controller 160 determining a malfunction of the power amplifier 112 the controller sends a signal to the module control input 134 thereby energizing the relay coil 240. As a result, the switch 230 isolates the isolatable output 220 from the circuit output 132 which in effect isolates the module signal input 128 from the circuit output 132 and directly couples the error cancellation input 133 to the circuit output 132.

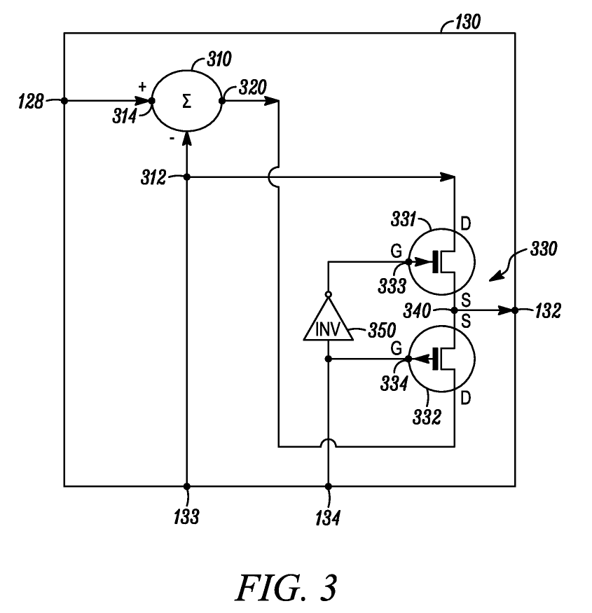

As will be apparent to a person skilled in they art, the switch 230 can be any form of switch such as one or more solid state devices or a stripline or a microstripline combined with Positive Intrinsic Negative (PIN) diodes. Referring to FIG. 3 there is illustrated another embodiment of the controllable error signal subtraction module 130 that comprises a selectable subtraction module 310 with an isolatable output 320 coupled through a switch 330 to the circuit output 132. The selectable subtraction module 310 has a module subtraction input 312 coupled to the error cancellation input 133 and a module addition input 314 coupled to the module signal input 128. The switch 330 is a complementary pair of transistors 331,332 controllable by the module control input 134. The complementary pair of transistors 331,332 have a common output 340 coupled to the circuit output 132 and transistor control inputs 333, 334 (Gates) of the complementary pair of transistors 331,332 are coupled by an inverter 350 thereby in operation the transistor control inputs 333, 334 are inverted with respect to each other.

The complementary pair of transistors 331,332 either directly couples the isolatable output 320 to the circuit output 132 (when transistor 331 is OFF and transistor 332 is ON) or alternatively isolates the isolatable output 320 from the circuit output 132 and directly couples the error cancellation input 133 to the circuit output 132 (when transistor 331 is ON and transistor 332 is OFF). It will therefore be apparent to a person skilled in that art that, in operation, when transistor 331 is OFF and transistor 332 is ON, the error signal subtraction module 310 performs subtraction of the error signal at an error cancellation input 133 from the module signal input 128. Also, upon the controller 160 determining a malfunction of the power amplifier 112 the controller sends a signal to the module control input 134 thereby driving transistor 331 ON and transistor 332 OFF. As a result, the switch 330 isolates the isolatable output 320 from the circuit output 132 which in effect isolates the module signal input 128 from the circuit output 132 and directly couples the error cancellation input 133 to the circuit output 132.

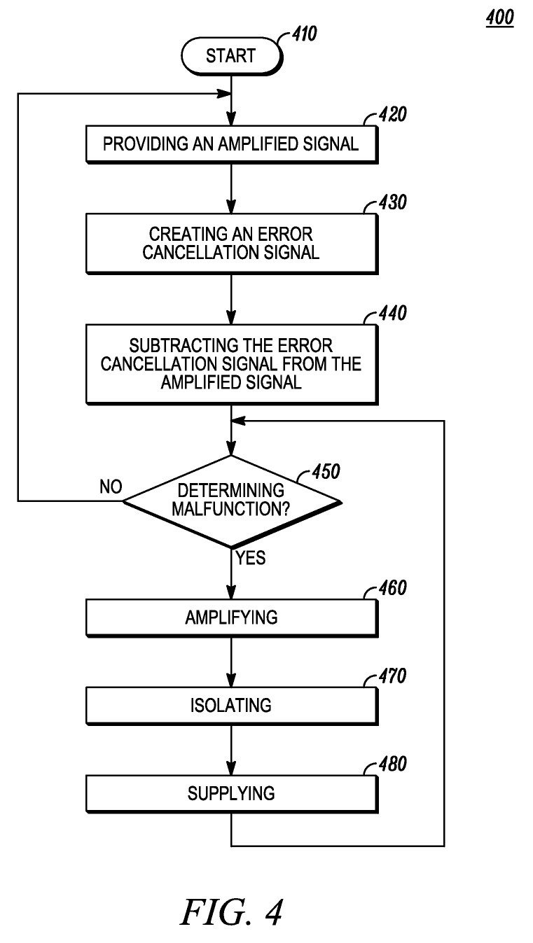

Referring to FIG. 4 there is illustrated a method 400 for controlling the feedforward amplifier circuit 100. The method 400 is initiated at a start block 410 upon power up of the feedforward amplifier circuit 100 the signal source 102 supplying an input signal to the first coupler signal input 104. At a providing block 420 the power amplifier provides 112 an amplified signal of an input signal. This amplified signal will typically have amplitude and phase distortions (distortions in the amplified signal) and will therefore it will not be an exact amplified version of the input signal. At a creating block 420, the feedforward subtraction module 146 performs an operation of creating an error cancellation signal indicative of the distortions in the amplified signal. The error cancellation signal is derived from subtracting a reduced amplitude version of the input signal, supplied to the subtraction input 144, from a reduced amplitude version of the amplified signal, supplied to the addition input 145, to provide an error signal that is amplified by an error signal amplifier 150 thereby creating the error cancellation signal. Next, at a subtracting block 440, the controllable error signal subtraction module 130 performs subtracting the error cancellation signal from the amplified signal to provide a corrected amplified signal at a circuit output 132 of the feedforward amplifier circuit 100. This corrected amplified signal ideally has most of the amplitude and phase distortions removed as the feedforward amplifier circuit 100 is designed so that error cancellation signal resembles the magnitude and phase of the distortions in the amplified signal.

At a determining malfunction test block 450, the controller 160 determines if there is a malfunction of the power amplifier and if the is such a malfunction the determining generates a malfunction signal indicative of the malfunction. This malfunction signal is supplied to the module control input 134. The determining is typically performed by the controller 160 monitoring signals at the first coupler tertiary output 108 and the second coupler tertiary output 122 and a malfunction is determined when the ARTV falls below a threshold value as described above. As an alternative, reduced current drawn by the power amplifier 112 could be used to detect the malfunction.

If at the determining malfunction test block 450 it is determined that there is no malfunction of the power amplifier 112 then the method 400 returns to the providing block 420. Alternatively, if the determining malfunction test block 450 determines that there is malfunction of the power amplifier 112 then the controller 160 generates the malfunction signal and the method 400 performs an amplifying operation at an amplifying block 460. At the amplifying block 460, the feedforward amplifier circuit 100 performs amplifying the reduced amplitude version of the input signal to provide an amplified version of the input signal. This amplifying at block 460 is performed by the error signal amplifier 150 is in response to the malfunction of the power amplifier 112. More specifically, amplifying the reduced amplitude version of the input signal automatically occurs when the power amplifier 112 is faulty (malfunctions) and does not provide the amplified signal. As a result, there is no reduced amplitude version of the amplified signal supplied to the addition input 145 and thus the output from the feedforward subtraction module 164, supplied to the error signal amplifier 150, is the reduced amplitude version of the input signal.

In response to the malfunction signal being supplied to module control input 134 the controllable error signal subtraction module 130, at an isolating block 470, performs isolating the corrected amplified signal from the circuit output. Also, in response to the malfunction signal being supplied to module control input 134 the controllable error signal subtraction module 130, at a supplying block 480, performs supplying to the circuit output, the amplified version of the input signal, the supplying being in response to the malfunction signal. The method 400 then returns to determining malfunction test block 450 and only terminates when power down of the feedforward amplifier circuit 100 occurs. In one embodiment, in response to the malfunction the controller 160 may perform an operation of removing power supplied to the power amplifier 112; this can provide for reduced power consumption and may also reduce noise and distortions in the amplified version of the input signal. Also, the controller 160, with additional circuitry (not shown) can control the gain of the error signal amplifier 150 thereby increasing the amplitude of the amplified version of the input signal.

Advantageously, the present invention provides an alternative to fault tolerance using hardware redundancy to improve reliability of an amplifier. When the controller 160 detects a malfunction of the power amplifier 112 the feedforward amplifier circuit1 100 is re-configured so that the error signal amplifier 150 performs the amplification function of the power amplifier 112. The amplified version of the input signal provided by the error signal amplifier 150 will typically be of a lower quality than the amplified signal from the power amplifier 112 that under normal malfunction free conditions is provided at the circuit output. However, the present invention provides a cost effective fault tolerant alternative for use in mission critical devises or otherwise.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention. The benefits, advantages, solutions to problems, and any elements that may cause any benefit, advantage, or solution to occur or become more pronounced are not to be construed as critical, required, or essential features or elements of any or all of the claims. The invention is defined solely by the appended claims including any amendments made during the pendency of this application and all equivalents of those claims.

1. A feedforward amplifier circuit comprising:
a first coupler with a first coupler signal input, a first coupler signal output and a first coupler tertiary output;
a power amplifier with a power amplifier output and a power amplifier input, the power amplifier input being coupled to the first coupler signal output;
a second coupler having a second coupler input coupled to the power amplifier output, a second coupler signal output and a second coupler tertiary output;
a first delay circuit;
a controllable error signal subtraction module with a module signal input coupled through the first delay circuit to the second coupler signal output, the controllable error signal subtraction module having a circuit output, an error cancellation input and a module control input;
a second delay circuit;
a feedforward subtraction module with a feedforward subtraction module output, a subtraction input coupled through the second delay circuit to the first coupler tertiary output, and an addition input coupled to the second coupler tertiary output;
an error signal amplifier coupling the feedforward subtraction module output to the error cancellation input; and
a controller with a control output coupled to the module control input,
wherein, in operation the controllable error signal subtraction module performs subtraction of an error cancellation signal at the error cancellation input from the module signal input and upon the controller determining a malfunction of the power amplifier, the controller sends a signal to the module control input resulting in the controllable error signal subtraction module isolating the module signal input from the circuit output and directly coupling the error cancellation input to the circuit output.

2. A feedforward amplifier circuit as claimed in claim 1, wherein the controller determines the malfunction of the power amplifier by monitoring signals at the first coupler tertiary output and the second coupler tertiary output.

3. A feedforward amplifier circuit as claimed in claim 1, wherein the first delay circuit provides a time delay to compensate for propagation delays in the error signal amplifier and feedforward subtraction module.

4. A feedforward amplifier circuit as claimed in claim 1, wherein the second delay circuit provides a time delay to compensate for propagation delays in the power amplifier.

5. A feedforward amplifier circuit as claimed in claim 1, wherein the controllable error signal subtraction module comprises a selectable subtraction module with an isolatable output coupled through a switch to the circuit output.

6. A feedforward amplifier circuit as claimed in claim 5, wherein the selectable subtraction module has a module subtraction input coupled to the error cancellation input and a module addition input coupled to the module signal input.

7. A feedforward amplifier circuit as claimed in claim 6, wherein the switch either directly couples the isolatable output to the circuit output or alternatively isolates the isolatable output from the circuit output and directly couples the error cancellation input to the circuit output.

8. A feedforward amplifier circuit as claimed in claim 7, wherein the switch is a reed relay controllable by the module control input.

9. A feedforward amplifier circuit as claimed in claim 7, wherein the switch is a complementary pair of transistors controllable by the module control input.

10. A feedforward amplifier circuit as claimed in claim 9, wherein the complementary pair of transistors has a common output coupled to the circuit output and transistor control inputs of the complementary pair of transistors are coupled by an inverter thereby in operation the transistor control inputs are inverted with respect to each other.

11. A method for controlling a feedforward amplifier circuit, the method comprising:
providing, from a power amplifier, an amplified signal of an input signal;
creating an error cancellation signal indicative of distortions in the amplified signal, the error cancellation signal being derived from subtracting a reduced amplitude version of the input signal from a reduced amplitude version of the amplified signal to provide an error signal that is amplified by an error signal amplifier thereby creating the error cancellation signal;
subtracting the error cancellation signal from the amplified signal to provide a corrected amplified signal at a circuit output of the feedforward amplifier circuit;
determining malfunction of the power amplifier, the determining generating a malfunction signal indicative of the malfunction;
amplifying the reduced amplitude version of the input signal to provide an amplified version of the input signal, the amplifying being performed by the error signal amplifier in response to the malfunction of the power amplifier;
isolating the corrected amplified signal from the circuit output, the isolating being in response to the malfunction signal; and
supplying to the circuit output, the amplified version of the input signal, the supplying being in response to the malfunction signal.

12. A method for controlling a feedforward amplifier circuit, as claimed in claim 11, wherein the determining the malfunction of the power amplifier is performed by detecting if the gain of the power amplifier falls below a threshold value.

13. A method for controlling a feedforward amplifier circuit, as claimed in claim 11, further comprising removing power supplied to the power amplifier in response to the malfunction.

14. A method for controlling a feedforward amplifier circuit, as claimed in claim 11, wherein the subtracting the error cancellation signal from the amplified signal isolating is performed by a selectable subtraction module with an isolatable output coupled through a switch to the circuit output.

15. A method for controlling a feedforward amplifier circuit, as claimed in claim 14, wherein selectable subtraction module has a module subtraction input that receives the amplified version of the input signal and the error cancellation signal, and the selectable subtraction module has a module addition input that receives the amplified signal.

16. A method for controlling a feedforward amplifier circuit, as claimed in claim 15, wherein the switch either directly couples the isolatable output to the circuit output or alternatively isolates the isolatable output from the circuit output and provides the supplying of amplified version of the input signal to the circuit output.
